(19) United States
(12) Patent Application Publication
(10) Pub. No.: US 2006/0065950 A1
(43) Pub. Date: Mar. 30, 2006

(54) Semiconductor device

(75) Inventors: Tatsuhiko Koide, Gifu-ken (JP); Yoshikazu Ibara, Gifu-ken (JP); Koichi Saito, Gifu-ken (JP); Daichi Suma, Gifu-ken (JP); Reiki Fujimori, Gifu-ken (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/239,105

(22) Filed: Sep. 30, 2005

(30) Foreign Application Priority Data
Sep. 30, 2004 (JP) 2004-285610
Oct. 19, 2004 (JP) 2004-304581
Oct. 21, 2004 (JP) 2004-307321

(51) Int. Cl. H01L 29/00

(52) U.S. Cl. 257/557

(57) ABSTRACT

A high performance semiconductor device including a silicon oxide film that surrounds an SiGe alloy layer, which functions as a base layer, and an n-type diffusion layer, which functions as an emitter layer. Under a polycrystalline silicon film, the silicon oxide film extends over a boundary between an active region and an element isolation film. After a flat interlayer dielectric is formed, a lead wire is connected to a silicide film located above the isolation film.

### CROSS-REFERENCE TO RELATED APPLICATIONS

This application is based upon and claims the benefit of priority from prior Japanese Patent Application No. 2004-285610, filed on Sep. 30, 2004, Japanese Patent Application No. 2004-304581, filed on Oct. 19, 2004, and Japanese Patent Application No. 2004-307321, filed on Oct. 21, 2004, the entire contents of which are incorporated herein by reference.

### BACKGROUND OF THE INVENTION

The present invention relates to a semiconductor device.

Portable electronics devices, such as cellular telephones, personal digital assistants (PDAs), digital video cameras (DVCs), and digital still cameras (DSCs), are increasingly becoming more sophisticated. The market demands compact and lightweight products. Highly integrated system large scale integration (LSI) technology is one solution for satisfying such market demand.

One module for realizing a highly integrated system LSI is a high-frequency bipolar transistor. A heterojunction bipolar transistor having a base layer fabricated with a silicon-germanium (SiGe) alloy is an example enabling a high-frequency bipolar transistor to exhibit higher performance.

Japanese Laid-Open Patent Publication No. 2002-16077 describes a method for manufacturing a heterojunction bipolar transistor including a SiGe alloy base layer. A bipolar transistor manufactured with the method described in the publication will now be described with reference to FIGS. 1 and 2. FIG. 1 is a plan view (layout view) showing the main part of a conventional bipolar transistor. FIG. 2 is a cross-sectional view of the transistor taken along line A-A′ in FIG. 1.

A p-type silicon substrate 110 has an embedded sub-collector layer 101. An oxide film, or element isolation film 103, is formed on the p-type silicon substrate 110 through local oxidation of silicon (LOCOS). An active region 102a surrounded by the element isolation film 103 is defined on the p-type silicon substrate 110. An epitaxially grown SiGe alloy layer 107, which functions as a base layer, is formed on the element isolation film 103 and the active region 102a. A base electrode 141 and a titanium silicide film 113 are formed on a portion of the element isolation film 103 that is leftward from the active region 102a. The base electrode 141 is made of an aluminum-silicon (AlSi) alloy. A collector opening, which extends to the embedded sub-collector layer 101, is formed in a portion of the element isolation film 103 that is rightward from the active region 102a. In the collector opening, a collector compensation region 105, a polycrystalline silicon film 111, and a titanium silicide film 113 are formed. A collector electrode 131, which is made of an AlSi alloy, is formed on the titanium silicide film 113. A silicon epitaxial layer 102, which is doped with phosphorous, is formed in the active region 102a excluding the element isolation film 103. The silicon epitaxial layer 102 functions as a collector layer. On the epitaxial layer 102, the SiGe alloy layer 107 (base layer), a silicon epitaxial film (emitter layer 108), a polycrystalline silicon film 111, and a titanium silicide film 113 are formed. An emitter electrode 121, which is made of an AlSi alloy, is formed on the titanium silicide film 113. A side wall 115, which is an insulative film, is formed around the emitter layer 108 and the polycrystalline silicon film 111.

In this conventional configuration, the emitter layer 108, the polycrystalline silicon film 111, and the titanium silicide film 113 on the polycrystalline silicon film 111 are formed to have the same size (area). The emitter electrode 121 is connected to the top surface of the titanium silicide film 113. Thus, the connection (contact) between the emitter electrode 121 and the titanium silicide film 113 is positioned right above the active region 102a of the transistor. To prevent deterioration of the device characteristic, it is preferable that the contact between the emitter electrode 121 and the titanium silicide film 113 be a normal contact and not have a borderless shape. Taking into consideration manufacturing errors, it is preferable that the contact be smaller than the width W of the emitter layer 108 (polycrystalline silicon film 111).

To enable the bipolar transistor of this conventional configuration to exhibit higher performance, the width W of the emitter layer 108 must be reduced. The emitter area is reduced by reducing the width of the emitter layer 108. As a result, parasitic capacitance and parasitic resistance are reduced, and the transistor has a superior high-frequency characteristic. The size of the contact needs to be reduced to reduce the width W of the emitter layer 108. However, the contact needs to have at least a predetermined area to allow a desired emitter current to flow. It is impossible to miniaturize the contact below a predetermined value. Semiconductor devices, such as bipolar transistors, are required to meet the demand for higher performance as well as the demand for further miniaturization.

### SUMMARY OF THE INVENTION

It is an object of the present invention to provide a high performance semiconductor device.

One aspect of the present invention is a semiconductor device including a semiconductor substrate. An element isolation film is formed on the semiconductor substrate. An active region is formed on the semiconductor substrate surrounded by the element isolation film. The active region functions as a collector layer. A base layer is formed on the active region. An emitter layer is formed on the base layer. A first insulative film covers a side of the emitter layer and a side of the base layer. A conductive film contacts the emitter layer and traverses the emitter layer, the first insulative film, and the element isolation film. A lead electrode is connected to a portion of the conductive film above the element isolation film. The first insulative film is formed under the conductive film so as to extend across a boundary between the active region and the element isolation film.

Another aspect of the present invention is a semiconductor device including a semiconductor substrate. An element isolation film is formed on the semiconductor substrate. An active region is surrounded by the element isolation film. The active region functions as a collector layer and has a surface. A base layer is formed on the active region. An emitter layer is formed on the base layer. A groove is formed in the surface of the active region between the base layer and the element isolation film. A first insulative film fills the groove. A second insulative film covers a side of the emitter layer and a side of the base layer. A conductive film contacts the emitter layer and traverses the emitter layer, the second insulative film, and the element isolation film. A lead electrode contacts the conductive film above the element isolation film. The second insulative film extends across a boundary between the first insulative film and the element isolation film under the conductive film.

A further aspect of the present invention is a semiconductor device including an element isolation film formed on a semiconductor substrate. An active region is surrounded by the element isolation film. The active region functions as a collector layer and has a surface. A base layer is formed on the active region. An emitter layer is formed on the base layer. An impurity region is formed in the surface of the active region between the base layer and the element isolation film. An insulative film covers a side of the emitter layer and a side of the base layer. A conductive film contacts the emitter layer and traverses the emitter layer, the insulative film, and the element isolation film. A lead electrode contacts the conductive film above the element isolation film. The active region contains conductive impurities. The impurity region is a region formed by adding reversed conductive impurities to the active region. The insulative film is formed under the conductive film so as to extend across a boundary between the impurity region and the element isolation film.

### BRIEF DESCRIPTION OF THE DRAWINGS

FIG. 1 is a plan view showing a conventional heterojunction bipolar transistor including a SiGe alloy base layer;

FIG. 2 is a cross-sectional view of the transistor taken along line A-A′ in FIG. 1;

FIG. 3 is a plan view of a semiconductor device according to a first embodiment of the present invention;

FIG. 4 is a cross-sectional view of the semiconductor device taken along line A-A′ in FIG. 3;

FIGS. 5 to 14 are cross-sectional views showing procedures for manufacturing the semiconductor device of FIG. 3;

FIGS. 15(a), 15(b), and 15(C) are cross-sectional views showing semiconductor devices of comparative examples 1, 2, and 3;

FIG. 15(d) is a cross-sectional view showing a semiconductor device of example 1;

FIG. 16 is a plan view showing a semiconductor device according to a second embodiment of the present invention;

FIG. 17 is a cross-sectional view of the semiconductor device taken on line A-A′ in FIG. 16;

FIGS. 18 to 28 are cross-sectional views showing procedures for manufacturing the semiconductor device of FIG. 16;

FIGS. 29(a) and 29(b) are cross-sectional views showing semiconductor devices of comparative examples 4 and 5;

FIG. 29(c) is a cross-sectional view showing a semiconductor device of example 2;

FIG. 30 is a cross-sectional view of a semiconductor device according to a third embodiment of the present invention;

FIG. 31 is a plan view of a semiconductor device according to a fourth embodiment of the present invention;

FIG. 32 is a cross-sectional view of the semiconductor device of FIG. 31;

FIGS. 33 to 43 are cross-sectional views showing the procedures for manufacturing the semiconductor device of FIG. 31;

FIG. 44 is a cross-sectional view of a semiconductor device according to a fifth embodiment of the present invention;

FIG. 45 is a cross-sectional view of a semiconductor device according to a sixth embodiment of the present invention; and

FIGS. 46 to 50 are cross-sectional views showing procedures for manufacturing the semiconductor device of the sixth embodiment.

### DETAILED DESCRIPTION OF THE PREFERRED EMBODIMENTS

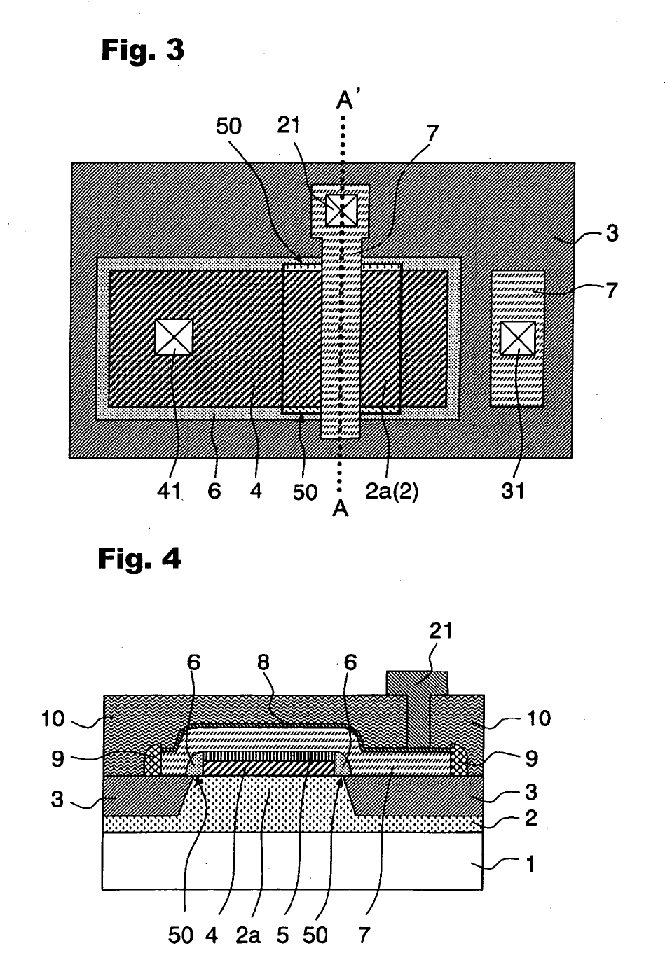

A semiconductor device according to a first embodiment of the present invention will now be described with reference to FIGS. 3 and 4.

An epitaxial layer 2, which functions as a collector layer, is formed on a silicon substrate 1. An element isolation film 3, which functions as a shallow trench isolation (STI) configuration, is formed on a portion of the epitaxial layer 2. A portion of the epitaxial layer 2 surrounded by the element isolation film 3 functions as an active region 2a. A SiGe alloy layer 4, which functions as a base layer, is formed on the active region 2a. An n-type diffusion layer 5, which functions as an emitter layer, is formed on the SiGe alloy layer 4. The n-type diffusion layer 5 is formed by diffusing n-type impurities in a polycrystalline silicon film 7 toward the SiGe alloy layer 4. The SiGe alloy layer 4 and the n-type diffusion layer 5 are surrounded by a side wall 6, which is formed by a silicon oxide film. The side wall 6 extends over the boundaries 50 between the active region 2a and the element isolation film 3. The polycrystalline silicon film 7 and a silicide film 8 are formed on the n-type diffusion layer 5. The polycrystalline silicon film 7 and the silicide film 8 cover portions of the n-type diffusion layer 5, the side wall 6, and the element isolation film 3. The polycrystalline silicon film 7 and the silicide film 8 are surrounded by a side wall 9, which is formed by an insulative film. An interlayer dielectric 10 is formed and flattened. Afterwards, a lead electrode 21 is formed. The lead electrode 21, which leads to the emitter layer (n-type diffusion layer 5), is connected to a portion of the silicide film 8 under which the element isolation film 3 is formed.

The SiGe alloy layer 4 is one example of a base layer. The side wall 6 is one example of an insulative film. The polycrystalline silicon film 7 is one example of a conductive film.

The side wall 6 is formed to extend over the boundaries 50 between the active region 2a and the element isolation film 3. This prevents the occurrence of a failure caused by a short circuit between the polycrystalline silicon film 7 and the collector layer (active region 2a). Further, the polycrystalline silicon film 7, which is connected to the emitter layer (n-type diffusion layer 5), is formed on the element isolation film 3. In other words, the lead electrode 21 is connected to the polycrystalline silicon film 7 even when the lead electrode 21 is not located right above the emitter layer 5. This satisfies the demand for reducing the width of the emitter layer 5 and the demand for maintaining the current flowing through the lead electrode 21 at a desired current value. As a result, the bipolar transistor (semiconductor device) exhibits higher performance.

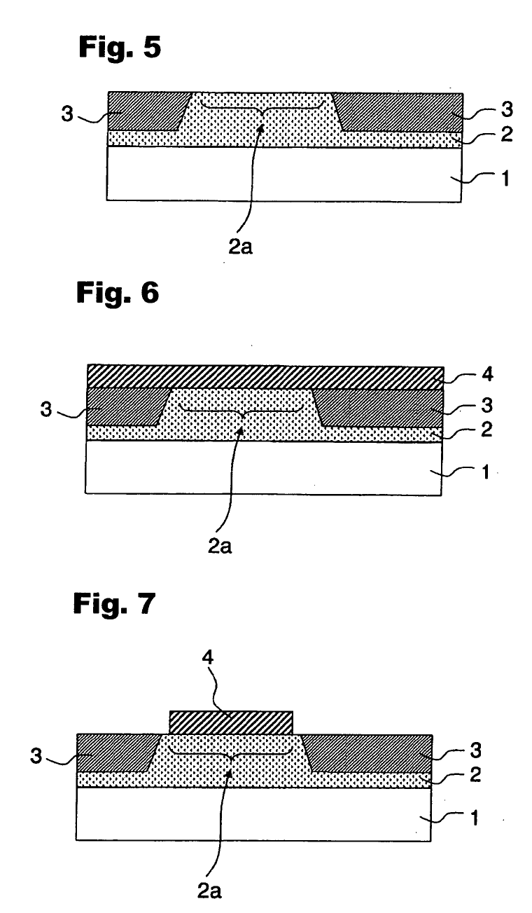

The procedures for manufacturing the semiconductor device of the first embodiment will now be described with reference to FIGS. 5 to 14.

[Process 1: Refer to FIG. 5]

First, an element isolation film 3 having for example the shallow trench isolation (STI) configuration is formed on a p-type silicon substrate 1. Then, ion implantation is performed to implant n-type impurities in a portion of a collector layer 2 to form an active region 2a. For example, phosphorus (P) is implanted with an electron acceleration energy of about 500 to 4000 keV at a concentration of about 3*10¹³ to 3*10¹⁵ cm⁻². After the implantation, heat treatment is performed at a temperature of about 1000° C. Further, a collector lead diffusion layer is formed (not shown).

[Process 2: Refer to FIG. 6]

A SiGe alloy layer 4, which is doped with boron (B) at a concentration of about 1*10¹⁹ cm⁻³ by CVD (chemical vapor deposition), is epitaxially grown. The thickness of the SiGe alloy layer 4 is about 10 to 100 nm and preferably about 80 nm. A portion of the SiGe alloy layer 4 that is on the collector layer 2 (active region 2a) is formed to have the same grating constant as its underlayer substrate (p-type silicon substrate 1) so that the portion of the SiGe alloy layer 4 on the collector layer 2 is formed as an epitaxial SiGe layer (not shown). A portion of the SiGe alloy layer 4 that is on the isolation layer 3 is polycrystallized so that the portion of the SiGe alloy layer 4 on the isolation layer 3 is formed as a polycrystalline SiGe layer (not shown).

The concentration of Ge in the SiGe alloy layer 4 may be uniform throughout the entire layer. Alternatively, the SiGe alloy layer 4 may employ graded doping that grades the Ge concentration to increase gradually from its front side (where an emitter layer is subsequently formed) toward the side where the collector layer 2 has been formed. In this case, the time taken by electrons to travel through the base layer is shortened. This enables the transistor to operate at high speeds. In this case, it is preferable that the Ge concentration be substantially about 0% at the front side of the SiGe alloy layer 4 and about 15% to 20% at the side of the SiGe alloy layer 4 where the collector layer 2 has been formed.

After and/or before the SiGe alloy layer 4 is formed, a silicon film that does not contain boron (B) or a SiGe alloy layer that does not contain boron (B) may be epitaxially grown by low-pressure CVD.

[Process 3: Refer to FIG. 7]

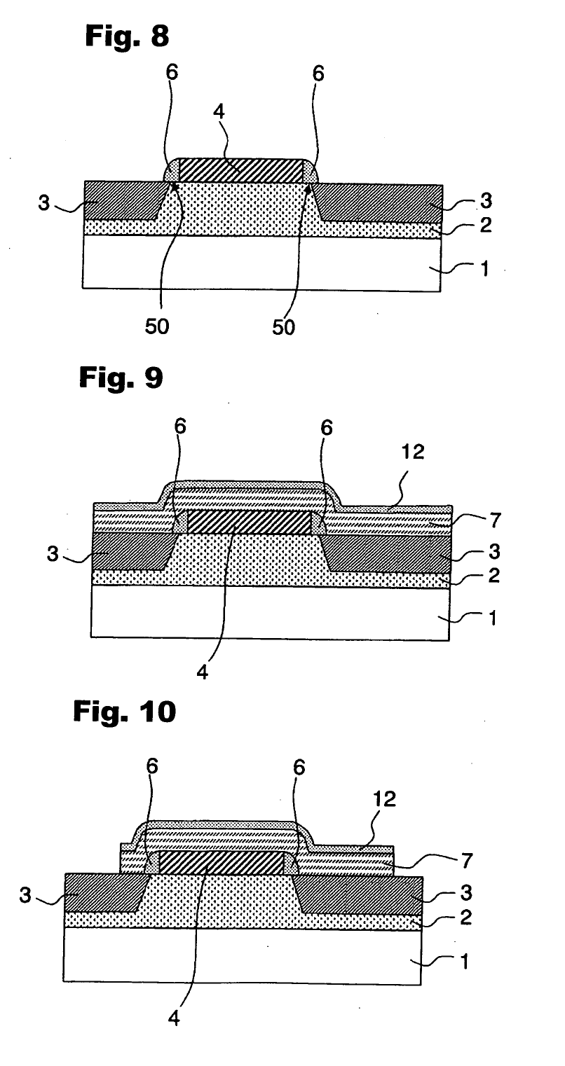

A resist pattern is formed using lithography. An unnecessary portion of the SiGe alloy layer 4 is removed by dry etching. This exposes a portion of the active region 2a. A side wall 6 is formed on the exposed portion of the active region 2a in a subsequent process.

[Process 4: Refer to FIG. 8]

A film of silicon oxide is formed by performing CVD. Then, the entire film surface is etched back by performing dry etching so that a silicon oxide film (side wall) 6 is formed to surround the SiGe alloy layer 4. As one example, the silicon oxide film 6 is formed by heating a mixture of tetra ethoxy silane (TEOS) and oxygen (O₂) at about 720° C. The thickness of the silicon oxide film 6 is in a range of about 10 to 200 nm, and is preferably about 100 nm. The side wall 6 at least covers the boundaries 50 between the active region 2a and the element isolation film 3. The side wall 6 prevents a polycrystalline silicon film 7, which is formed in a subsequent process, from coming in contact with the boundaries 50 between the active region 2a and the element isolation film 3.

[Process 5: Refer to FIG. 9]

A polycrystalline silicon film 7, which is doped with n-type impurities at a concentration of about 1*10²⁰ cm⁻³ or more, is formed by performing low-pressure CVD. A silicon nitride film 12 is formed on the polycrystalline silicon film 7. Arsenic (As) or phosphorus (P) may be used as the n-type impurities. The thickness of the polycrystalline silicon film 7 is about 100 to 300 nm. The thickness of the silicon nitride film 12 is about 50 to 200 nm.

[Process 6: Refer to FIG. 10]

A resist pattern is formed by performing lithography. Then, dry etching is performed to remove unnecessary portions of the silicon nitride film 12 and subsequently unnecessary portions of the polycrystalline silicon film 7. As shown in FIG. 3, subsequent to the etching, the remaining polycrystalline silicon film 7 comes in contact with and extends linearly across an n-type diffusion layer 5, which is formed in a subsequent process. The n-type diffusion layer 5 functions as an emitter layer. The two ends of the polycrystalline silicon film 7 are on the element isolation film 3. This enables the polycrystalline silicon film 7 to be processed so that a portion right above the active region 2a has a constant area (emitter-base junction area) even if the resist pattern is misaligned.

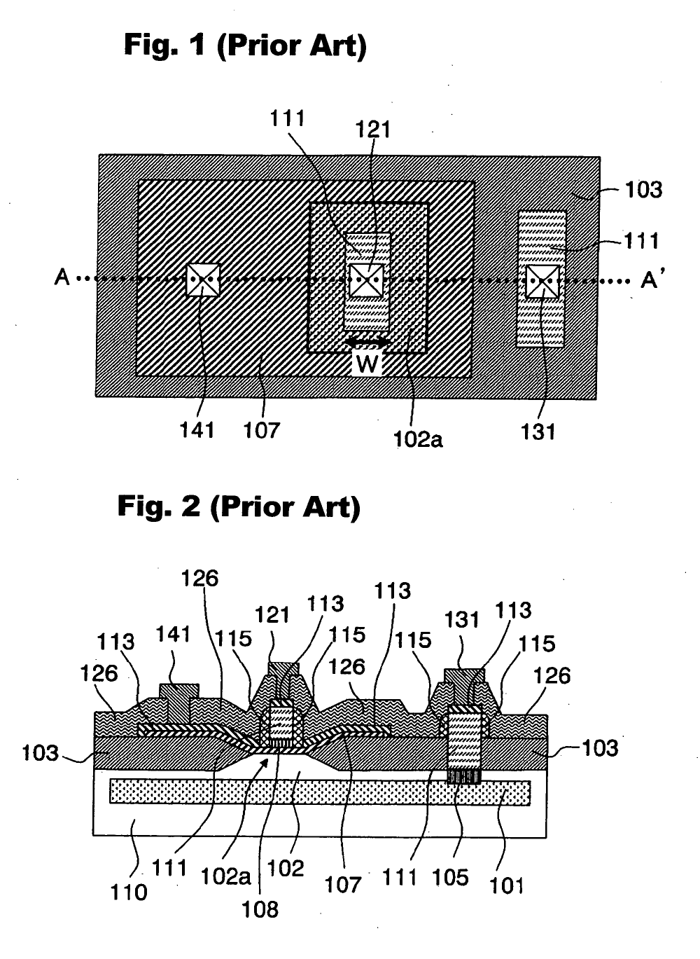

In the conventional structure shown in FIGS. 1 and 2, the emitter layer 108 is formed within the active region 102a. Thus, the emitter layer 8 and the polycrystalline silicon film 111 are formed to have the same area (size). To reduce the area of the emitter layer 108, the polycrystalline silicon film 111 needs to be processed in the form of a pillar. In the present invention, the portion of the polycrystalline silicon film 7 that is on the emitter layer 5 extends linearly. This eliminates the need for processing the polycrystalline silicon film 111 to be in the pillar form as required in the prior art. Thus, the present invention eliminates the need for a high precision lithography machine and reduces the manufacturing cost of the semiconductor device.

[Process 7: Refer to FIG. 11]

A film of silicon oxide is formed by performing CVD. Then, the entire film surface is etched back by performing dry etching so that a silicon oxide film (side wall) 9 is formed to surround the silicon nitride film 12 and the polycrystalline silicon film 7. As one example, the silicon oxide film 9 is formed by heating a mixture of tetra ethoxy silane (TEOS) and oxygen (O₂) at a temperature of about 720° C. The thickness of the silicon oxide film 9 is about 100 to 400 nm.

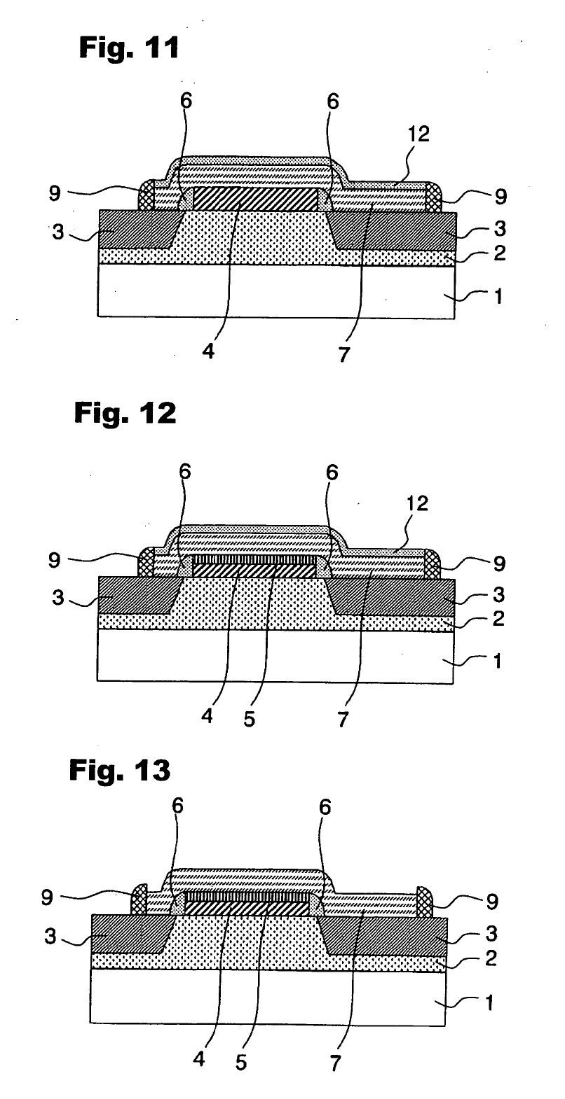

Although not shown in the drawings, a p⁺ diffusion layer, which functions as an external base layer, is formed. To form the p⁺ diffusion layer, a film of silicon oxide is first formed on the entire surface by low-pressure CVD, and ion implantation is performed to implant boron (B) in the silicon oxide film. Then, heat treatment is performed to activate the film to form the p+ diffusion layer. As one example, BF₂ may be implanted with an electron acceleration energy of about 1 to 30 keV with a concentration in a range of 1*10¹⁴ to 5*10¹⁵ cm⁻². Under such ion implantation conditions, ions do not pass through the silicon nitride film 12 having a thickness of about 100 nm, which is on the polycrystalline silicon film 7. Thus, boron is prevented from being implanted into the polycrystalline silicon film 7.

[Process 8: Refer to FIG. 12]

The structure is subjected to heat treatment to diffuse n-type impurities in the polycrystalline silicon film 7 into the SiGe alloy layer 4 to form an n-type diffusion layer 5. As a result, an emitter-base junction is formed in the SiGe alloy layer 4. Heat treatment is performed at a temperature of about 1050° C. for about 5 to 30 seconds with a rapid thermal annealing (RTA) apparatus.

[Process 9: Refer to FIG. 13]

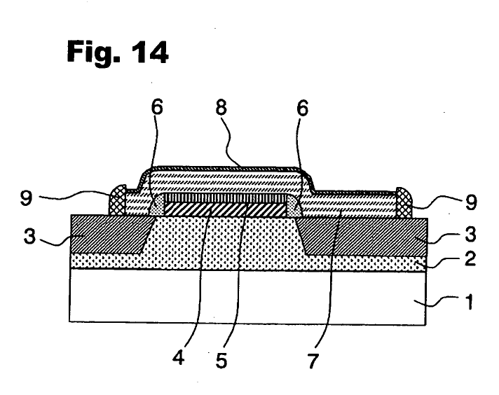

After the heat treatment, portions of the silicon oxide film (not shown) and the silicon nitride film 12 corresponding to a base electrode, an emitter electrode, and a collector electrode (not shown) are removed using diluted hydrofluoric acid and phosphoric acid.

[Process 10: Refer to FIG. 14]

A layer of cobalt (Co) is formed on the surface of the polycrystalline silicon film 7 and the surface of the p⁺ diffusion layer (not shown). The structure is then subjected to heat treatment to form a cobalt silicide film (silicide film) 8. The sheet resistance of the silicide film 8 is about 5 Ω/square, which is much lower than the sheet resistance of 100 Ω/square of the conventional p+ diffusion layer (not shown). Thus, the parasitic resistance generated between the internal base layer and a base lead electrode 41 (FIG. 3), which is connected to the external base layer, is reduced.

[Process 11: Refer to FIG. 3]

An interlayer dielectric 10, such as a plasma TEOS (tetraethyl orthosilicate) film, is deposited on a semiconductor substrate. A contact hole is formed in the dielectric 10. A barrier metal layer, which is made for example of titanium, and a conduction layer, which is made of aluminum or an aluminum alloy, are formed. A collector electrode 31, a base electrode 41, and an emitter electrode 21 of an NPN transistor are formed. This produces the bipolar transistor (semiconductor device) having an NPN transistor.

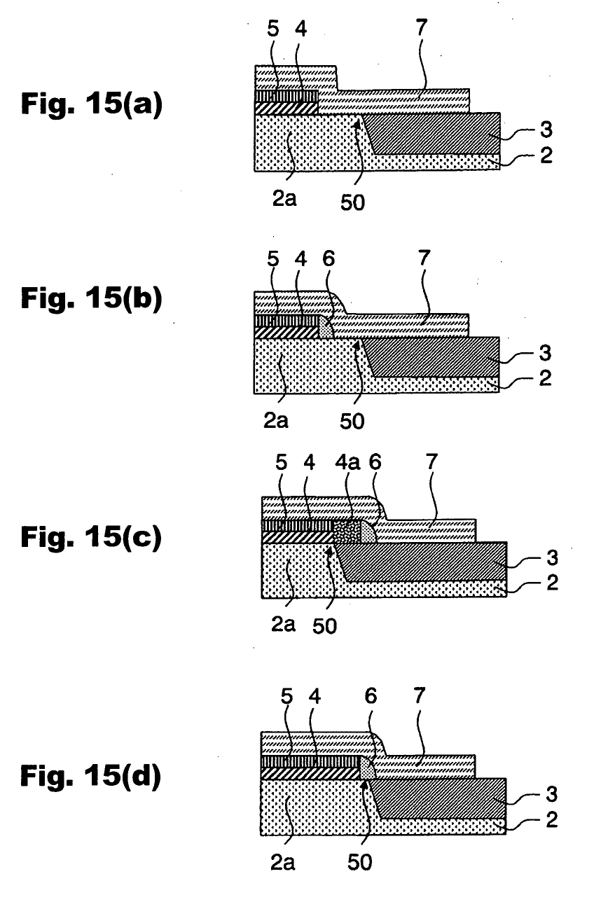

The relative position of the boundaries 50 between the active region 2a and the element isolation film 3 to the side wall 6 will now be described with reference to FIGS. 15(a) to 15(d). FIGS. 15(a), 15(b), and 15(c) are cross-sectional views showing semiconductor devices of comparative examples 1, 2, and 3. FIG. 15(d) is a cross-sectional view showing a semiconductor device according to example 1 of the present invention. In FIG. 15(a), the side wall 6 is not formed, and the polycrystalline silicon film 7 extends over the element isolation film 3. In FIG. 15(b), the boundaries 50 between the active region 2a and the element isolation film 3 are located outside the side wall 6. In FIG. 15(c), the boundaries 50 are located under the SiGe alloy layer 4, and the side wall 6 is located outside the boundaries 50. In FIG. 15(d), the side wall 6 extends over the boundaries 50.

In comparative examples 1 and 2 shown in FIGS. 15(a) and 15(b), the polycrystalline silicon film 7 directly comes in contact with the active region 2a of the collector layer 2. This short circuits the emitter and collector. As a result, these bipolar transistors (semiconductor devices) fail to operate.

In the comparative example 3 of FIG. 15(c), a portion of the SiGe alloy layer 4 that is on the element isolation film 3 has a different film quality from that of the epitaxial SiGe alloy layer 4 functioning as a base layer. Thus, the portion of the SiGe alloy layer 4 that is on the element isolation film 3 is polycrystallized and is formed as a polycrystalline SiGe layer 4a. This short circuits the emitter and base via the polycrystalline SiGe layer 4a. As a result, the bipolar transistor (semiconductor device) fails to operate. This is a typical phenomenon observed when a SiGe alloy layer is formed. On an epitaxial underlayer (single crystal underlayer), such as on the active region 2a, a SiGe alloy layer inherits the crystalline characteristic of the underlayer. In this case, the layer is formed as an epitaxial SiGe alloy layer. However, on an underlayer other than a crystal underlayer, for example, on an insulative film underlayer such as the element isolation film 3, the underlayer has no crystalline characteristic and crystal growth (epitaxial growth) thus does not occur. In this case, the layer is formed as a polycrystalline SiGe layer.

In the example 1 of FIG. 15(d), the side wall 6, which is arranged between the polycrystalline silicon film 7 and the collector layer (active region 2a), prevents short circuiting between the emitter and collector. The SiGe alloy layer portion that functions as a base layer is completely formed on the collector layer (active region 2a). This prevents a polycrystalline SiGe layer from being formed and prevents short circuiting between the emitter and collector.

As described above, the polycrystalline silicon film 7 may be formed to extend over the element isolation film 3 only when the side wall 6 extends over the boundaries 50 between the active region 2a and the element isolation film 3. This enables a polycrystalline silicon film portion that comes in contact with the emitter layer and a polycrystalline silicon film portion that comes in contact with the lead electrode to be processed independently. Thus, this satisfies both demands for reducing the width of the emitter and maintaining the current flowing through the lead electrode at a desired current value, which are required to realize a higher performance bipolar transistor (semiconductor device).

The first embodiment has the advantages described below.

The conductive film, which is connected to the emitter layer, is arranged on the element isolation film. This enables the lead electrode to be connected to the conductive film without depending on the width of the emitter and without failing to maintain the current flowing through the lead wire at a desired current value. As a result, a higher performance semiconductor device, such as a bipolar transistor, is manufactured at a low cost.

The conductive film comes in contact with the emitter layer and extends linearly. The two ends of the conductive film are located on the element isolation film. Even if the resist pattern is misaligned in the lithography process when performing etching to form the conductive film, the conductive film is processed so that its portion right above the active region has a fixed area (emitter-base junction area). As a result, a semiconductor device having stable performance, such as a bipolar transistor, is manufactured at low cost.

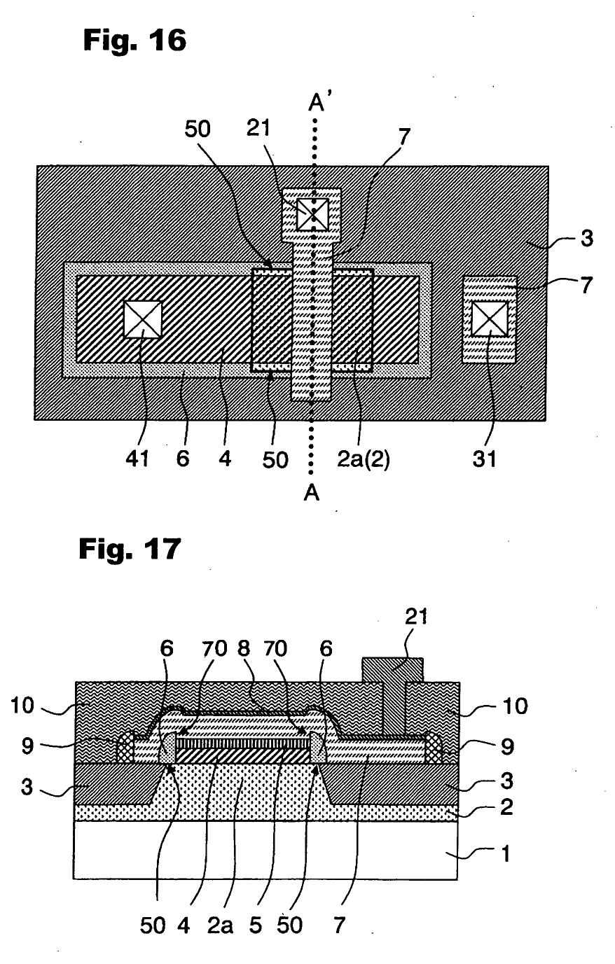

A heterojunction bipolar transistor including a SiGe alloy base layer according to a second embodiment of the present invention will now be described with reference to FIG. 16, focusing on its differences from the transistor of the first embodiment.

A side wall 6 includes projections 70, which project from the top surface of an n-type diffusion layer 5. The projections 70 of the side wall 6 function as a barrier against diffusion of impurities contained in region A (refer to FIG. 26) of a polycrystalline silicon film 7. Region A of the polycrystalline silicon film 7 is located right above the side wall 6. Further, the projections 70 of the side wall 6 function to increase the distance from region A of the polycrystalline silicon film 7 to the corresponding end (interface between the SiGe alloy layer 4 and the side wall 6) of the SiGe alloy layer 4. This decreases the amount of impurities moving from region A of the polycrystalline silicon film 7 to the end of the SiGe alloy layer 4. In other words, this prevents an excess amount of n-type impurities from being diffused from region A of the polycrystalline silicon film 7 to the end of the SiGe alloy layer 4. As a result, the pressure resistance between the emitter layer (n-type diffusion layer 5) and the collector layer (active region 2a) is kept high.

As in the first embodiment, the side wall 6 extends over the boundaries 50 between the active region 2a and the element isolation film 3. Thus, the second embodiment has the same advantages as the first embodiment.

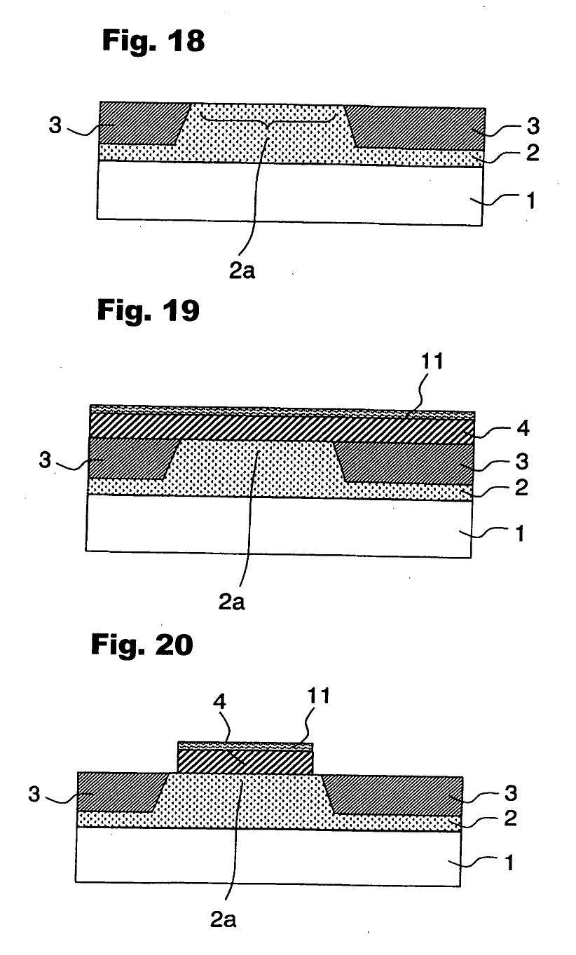

FIGS. 18 to 28 are cross-sectional views showing the procedures for manufacturing the semiconductor device of the second embodiment.

[Process 1: Refer to FIG. 18]

First, an element isolation film 3, such as an STI film, is formed on a p-type silicon substrate 1. Then, ion implantation is performed to implant n-type impurities in a portion of a collector layer 2 to form an active region 2a. For example, phosphorus (P) is implanted with an electron acceleration energy of about 500 to 4000 keV at a concentration of about 3*10¹³ to 3*10¹⁵ cm². After the implantation, the structure is subjected to heat treatment at a temperature of about 1000° C. Further, a diffusion layer for a collector lead is formed (not shown).

[Process 2: Refer to FIG. 19]

A SiGe alloy layer 4, which is doped with boron (B) at a concentration of about 1*10¹⁹ cm⁻³ by CVD (chemical vapor deposition), is epitaxially grown. The thickness of the SiGe alloy layer 4 is about 80 nm. A portion of the SiGe alloy layer 4 that is on the active region 2a is formed to have the same grating constant as its underlayer substrate (p-type silicon substrate 1) so that the portion of the SiGe alloy layer 4 on the active region 2a is formed as an epitaxial SiGe layer. A portion of the SiGe alloy layer 4 that is on the isolation layer 3 is polycrystallized so that the portion of the SiGe alloy layer 4 on the isolation layer 3 is formed as a polycrystalline SiGe layer.

The concentration of Ge in the SiGe alloy layer 4 may be uniform throughout the entire layer. Alternatively, the SiGe alloy layer 4 may employ graded doping that grades the Ge concentration to increase gradually from its front side (where an emitter layer is subsequently formed) toward the side where the collector layer 2 has been formed. In this case, the time taken by electrons to travel through the base layer is shortened. This enables the transistor to operate at high speeds. In this case, it is preferable that the Ge concentration be substantially about 0% at the front side of the SiGe alloy layer 4 and about 15 to 20% at the side of the SiGe alloy layer 4 where the collector layer 2 has been formed.

After and/or before the SiGe alloy layer 4 is formed, a silicon film that does not contain boron (B), or a SiGe alloy layer that does not contain boron (B) may be epitaxially grown by low-pressure CVD.

Next, a silicon nitride film 11 is formed on the SiGe alloy layer 4 by performing CVD. The thickness of the silicon nitride film 11 is about 100 nm.

[Process 3: Refer to FIG. 20]

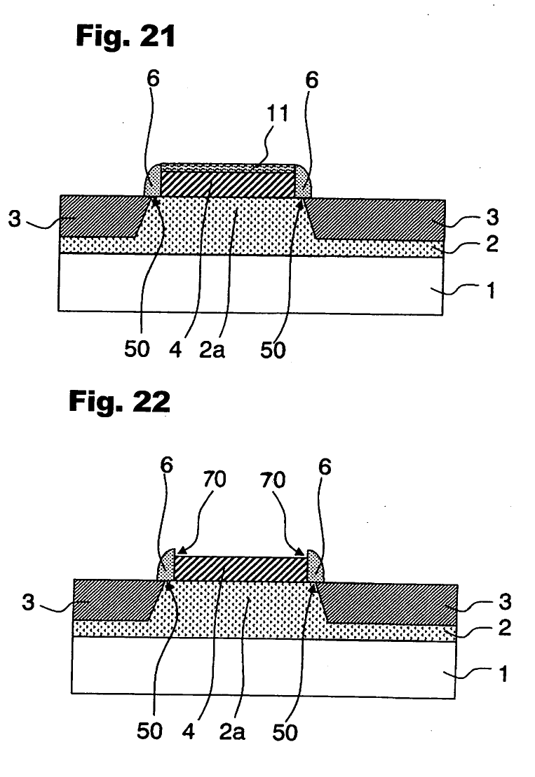

A resist pattern is formed by performing lithography. Unnecessary portions of the silicon nitride film 11 and the SiGe alloy layer 4 are removed by performing dry etching. This exposes a portion of the active region 2a. The shape of the resist pattern is adjusted in a manner that the exposed amount of the active region 2a would be about 50 nm. A side wall 6 is formed on the exposed portion of the active region 2a in a subsequent process.

[Process 4: Refer to FIG. 21]

A film of silicon oxide is formed by performing CVD. Then, the entire film surface is etched back by performing dry etching so that a silicon oxide film (side wall) 6 is formed to surround the silicon nitride film 11 and the SiGe alloy layer 4. As one example, the silicon oxide film 6 is formed by heating a mixture of tetra ethoxy silane (TEOS) and oxygen (O₂) at about 720° C. The thickness of the silicon oxide film 6 is about 200 nm. A portion of the side wall 6, which is under a polycrystalline silicon film 7 formed subsequently, covers at least the boundaries 50 between the active region 2a and the element isolation film 3.

[Process 5: Refer to FIG. 22]

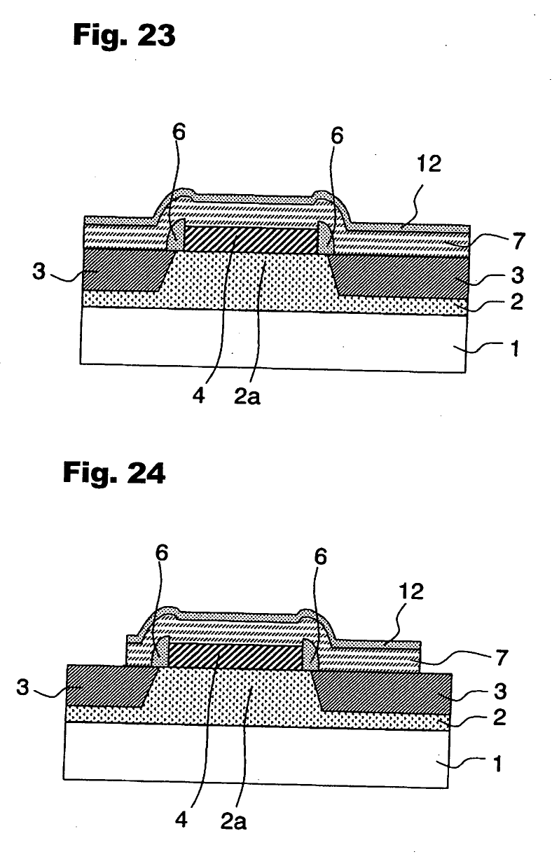

Only the silicon nitride film 11 is selectively removed by wet etching using phosphoric acid. As a result, the top portion of the side wall 6 projects from the top surface of the SiGe alloy layer 4 (corresponding to the top surface of the n-type diffusion layer 5 described later). The amount by which projections 70 of the side wall 6 projects, that is, the height of portions of the side wall 6 that extends above the top surface of the SiGe alloy layer 4, is freely adjustable by increasing or decreasing the thickness of the silicon nitride film 11.

[Process 6: Refer to FIG. 23]

A polycrystalline silicon film 7, which is doped with n-type impurities at a concentration of about 1*10²⁰ cm⁻³ or more, is formed by performing low-pressure CVD. A silicon nitride film 12 is formed on the polycrystalline silicon film 7. Arsenic (As) or phosphorus (P) may be used as the n-type impurities. The thickness of the polycrystalline silicon film 7 is about 200 nm. The thickness of the silicon nitride film 12 is about 100 nm.

[Process 7: Refer to FIG. 24]

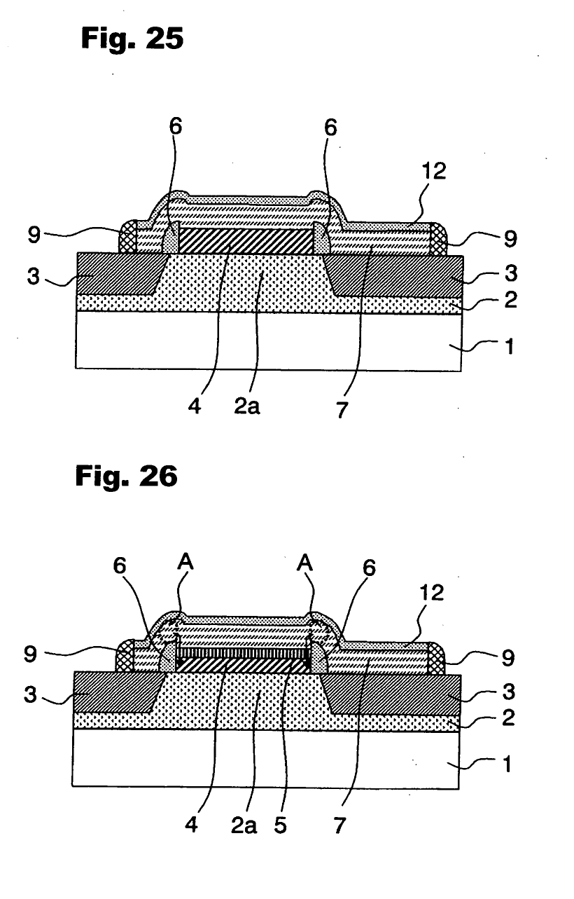

A resist pattern is formed by performing lithography. Dry etching is performed to remove an unnecessary portion of the silicon nitride film 12 and then an unnecessary portion of the polycrystalline silicon film 7. As in the first embodiment, the polycrystalline silicon film 7 comes in contact with and extends linearly across an n-type diffusion layer 5, which functions as an emitter layer. The two ends of the polycrystalline silicon film 7 are on the element isolation film 3.

[Process 8: Refer to FIG. 25]

A film of silicon oxide is formed by performing CVD. Then, the entire film surface is etched back by performing dry etching so that a silicon oxide film (side wall) 9 is formed to surround the silicon nitride film 12 and the polycrystalline silicon film 7. For example, the silicon oxide film 9 may be formed by heating a mixture of tetra ethoxy silane (TEOS) and oxygen (O₂) at a temperature of about 720° C. The thickness of the silicon oxide film 9 is about 200 nm.

[Process 9: Refer to FIG. 26]

The structure is subjected to heat treatment to cause the n-type impurities in the polycrystalline silicon film 7 to diffuse into the SiGe alloy layer 4 and form an n-type diffusion layer 5. As a result, an emitter-base junction is formed in the SiGe alloy layer 4. A rapid thermal annealing (RTA) apparatus performs the heat treatment at a temperature of about 1050° C. for about 5 to 30 seconds.

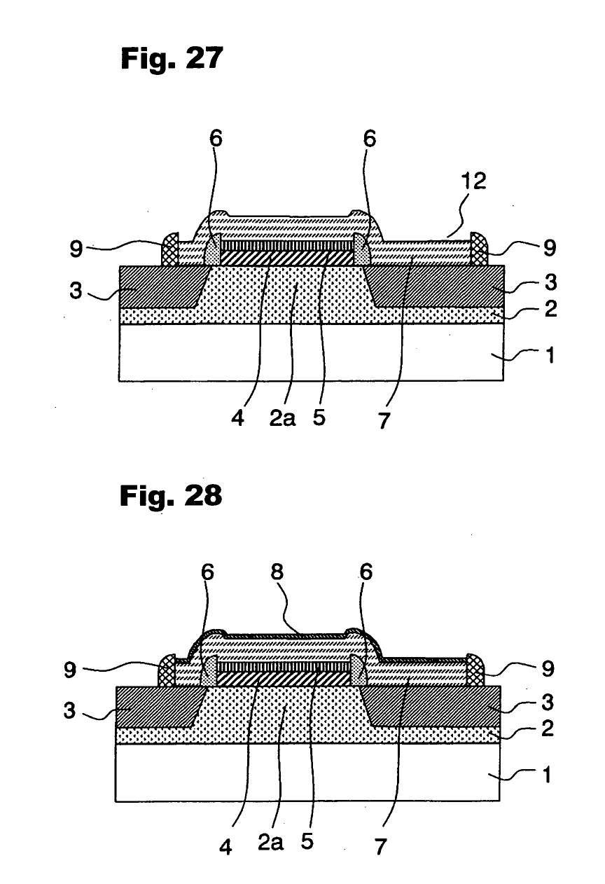

In the diffusion of the impurities, the side wall 6, which completely covers a side surface (side surface of the portion that functions as an emitter layer) of the SiGe alloy layer 4, prevents the impurities from diffusing from the polycrystalline silicon film 7 to the end of the SiGe alloy layer 4. As a result, the profile of the impurity concentration in the depthwise direction of the n-type diffusion layer 5 is stabilized.

[Process 10: Refer to FIG. 27]

After the heat treatment, portions of the silicon oxide film and the silicon nitride film 12 corresponding to an emitter electrode are removed using diluted hydrofluoric acid and phosphoric acid. Although not shown in the drawings, portions of the silicon oxide film and the silicon nitride film 12 corresponding to a base electrode and a collector electrode are also removed at the same time.

[Process 11: Refer to FIG. 28]

A layer of cobalt (Co) is formed on the surface of the polycrystalline silicon film 7 and the surface of the p⁺ diffusion layer (not shown), which functions as an external base layer. The structure is then subjected to heat treatment to form a cobalt silicide film (silicide film) 8. The sheet resistance of the silicide film 8 is relatively low. Thus, the parasitic resistance generated between the internal base layer and the base lead electrode 41 (refer to FIG. 16), which is coupled to the external base layer, is reduced.

[Process 12: Refer to FIG. 17]

An interlayer dielectric 10, such as a plasma TEOS (tetraethyl orthosilicate) film, is deposited on a semiconductor substrate. A contact hole is formed in the dielectric 10. A barrier metal layer, which is made of, for example, titanium, and a conduction layer, which is made of aluminum or an aluminum alloy, are formed. A collector electrode 31, a base electrode 41, and an emitter electrode 21 of an NPN transistor are formed. In this way, the bipolar transistor (semiconductor device) having an NPN transistor is manufactured.

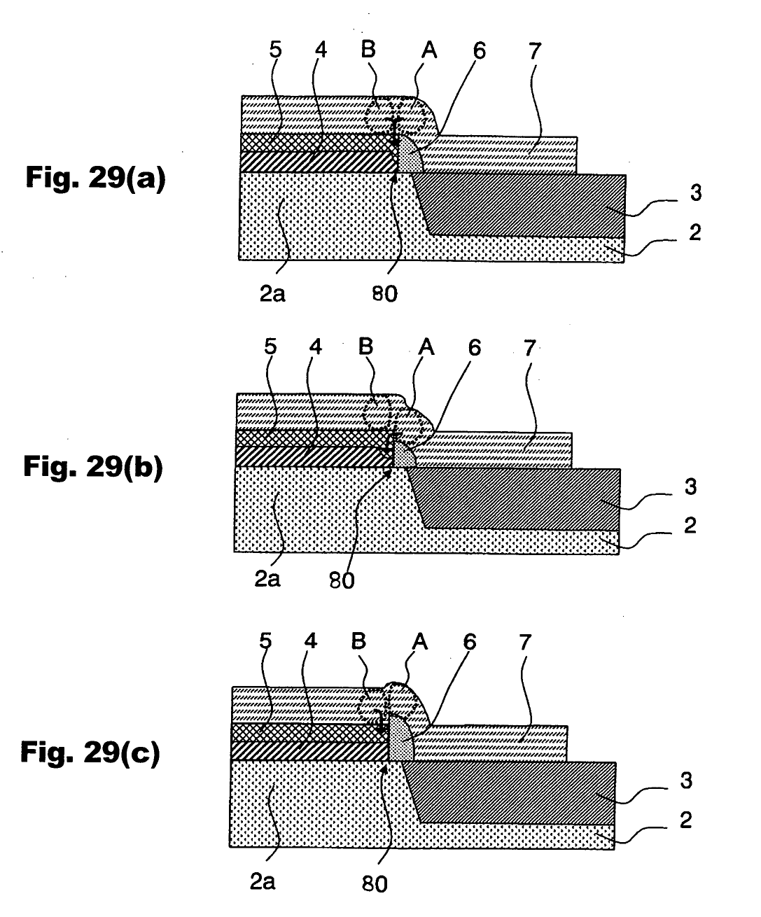

The effect of the projections 70, which projects above the n-type diffusion layer 5, will now be described with reference to FIGS. 29(a) to 29(c). FIG. 29(a) shows comparative example 4, in which the top portion of the side wall 6 is flush with the top surface of the n-type diffusion layer 5. FIG. 29(b) shows comparative example 5, in which the top portion of the side wall 6 is lower than the top surface of the n-type diffusion layer 5. FIG. 29(c) shows example 2, in which the top portion of the side wall 6 is higher than the top surface of the n-type diffusion layer 5.

In the etching of the SiGe alloy layer 4, a large number of crystal defects occur in the end of the SiGe alloy layer 4, which includes the side surface of the SiGe alloy layer 4 (the same applies to the n-type diffusion layer 5). Such crystal defects may cause abnormal diffusion of impurities to the end of the SiGe alloy layer 4. Alternatively, such crystal defects may accelerate the diffusion speed of the impurities. When such a phenomenon occurs, the profile of the impurity concentration in the depth direction of the n-type diffusion layer 5 is unstable.

In FIG. 29(a), the impurities contained in region A of the polycrystalline silicon film 7, which is located right above the side wall 6, diffuses in the same manner as the impurities contained in region B of the polycrystalline silicon film 7, which is located right above the SiGe alloy layer 4. The impurities that have diffused deeply in the vicinity of an interface 80 between the SiGe alloy layer 4 and the side wall 6 lowers the pressure resistance between the emitter (n-type diffusion layer 5) and the collector (active region 2a).

Further, differences during the manufacturing process may cause a portion of the side wall 6 to be excessively etched back. This exposes portions of a side surface of the SiGe alloy layer 4 corresponding to the excessively etched back portion of the side wall 6. In this case, for the reasons described below with reference to comparative example 3 of FIG. 29(b), failures may be caused by a lowered pressure resistance or an emitter-collector short circuit.

In FIG. 29(b), the impurities contained in region A diffuse via the exposed side surface portion of the SiGe alloy layer 4. Thus, the impurities contained in region A diffuses deeper into the SiGe alloy layer 4 than the impurities contained in region B. As a result, the n-type diffusion layer 5 is formed deeply in the interface 80. This lowers the pressure resistance between the emitter (n-type diffusion layer 5) and the collector (active region 2a). Such a lowered pressure resistance may cause an emitter-collector short circuit.

In FIG. 29(c), the projections 70 of the side wall 6 function to increase the distance from region A of the polycrystalline silicon film 7 located right above the side wall 6 to the SiGe alloy layer 4. Further, the projections 70 of the side wall 6 function as a barrier against the diffusion of the impurities from region A. This reduces the amount of impurities reaching the end of the SiGe alloy layer 4. In particular, when the height of the projections 70 of the side wall 6 that extend above the top surface of the n-type diffusion layer 5 is greater than or equal to the thickness of the SiGe alloy layer 4, a portion of the impurities contained in region A is completely prevented from reaching the bottom surface of the SiGe alloy layer 4. Thus, only the impurities contained in region B reaches the end of the SiGe alloy layer 4. As a result, an excess amount of impurities is prevented from diffusing to the end of the SiGe alloy layer 4. The profile of the impurity concentration in the depthwise direction of the n-type diffusion layer 5 is stabilized, and the pressure resistance between the emitter layer (n-type diffusion layer 5) and the collector layer (active region 2a) is kept high.

The side wall 6 completely covers the side surface of the SiGe alloy layer 4. Thus, the impurities in the polycrystalline silicon film 7 are prevented from diffusing to the SiGe alloy layer 4 via the side surface of the SiGe alloy layer 4. Even if differences in the etch back cause a portion of the side wall 6 to be excessively etched back, the projections 70 of the side wall 6 functions as a margin for such excessive etching and prevents the side surface of the SiGe alloy layer 4 from being exposed. In particular, assuming that the film thickness of the insulative film before the side wall 6 is etched back is Tₓ [nm] and that the manufacturing difference of etch back is Y [%], the side surface of the SiGe alloy layer 4 is completely prevented from being exposed when the height (thickness) of the portion of the side wall 6 that extends above the SiGe alloy layer 4 is greater than or equal to Tₓ*Y/100 [m]. Thus, the impurities in the polycrystalline silicon film 7 above the side wall 6 is prevented from being diffused to the SiGe alloy layer 4 via the side surface of the SiGe alloy layer 4. The pressure resistance between the emitter layer and the collector layer is prevented from being lowered.

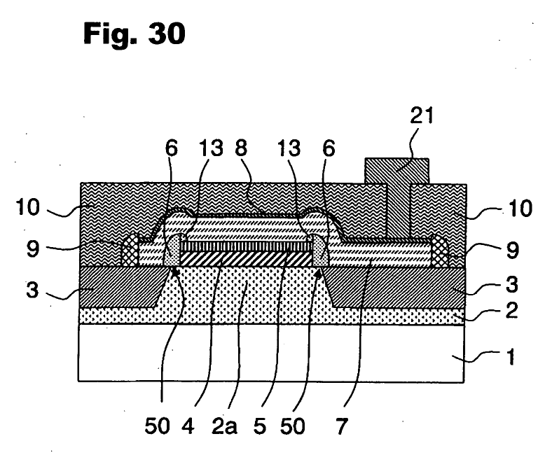

A heterojunction bipolar transistor including a SiGe alloy base layer according to a third embodiment of the present invention will now be described with reference to FIG. 30 focusing on its differences from the transistor of the second embodiment.

In the third embodiment, a side wall 13, which is a silicon oxide film, is further formed on an n-type diffusion layer 5 to cover an inner wall of projections 70 of a side wall 6. The side wall 13 covers the boundaries (inner edges) between the top surface of the n-type diffusion layer 5 and the side wall 6. The side wall 13 is one example of a second insulative film.

The side wall 13 functions to reduce the amount of impurities in a portion of a polycrystalline silicon film 7 above the side wall 6 (region A) that reach an end (interface 70) of a SiGe alloy layer 4. This prevents an excess amount of impurities in the polycrystalline silicon film 7 above the side wall 6 from diffusing along the end of the SiGe alloy layer 4. The pressure resistance between the emitter layer (n-type diffusion layer 5) and the collector layer (active region 2a) is kept high.

A heterojunction bipolar transistor including a SiGe alloy base layer according to a fourth embodiment of the present invention will now be described with reference to FIG. 31 focusing on its differences from the transistor of the first embodiment.

In the fourth embodiment, grooves 60 are formed in the surface of an active region 2a located between a SiGe alloy layer 4 and an element isolation film 3. The grooves 60 are filled with portions of a side wall 6. The SiGe alloy layer 4 is one example of a base layer of the present invention, the side wall 6 is one example of a first insulative film and a second insulative film of the present invention, and the polycrystalline silicon film 7 is one example of a conductive film of the present invention.

The grooves 60, which are filled with portions of the side wall 6, are formed in the surface of the active region 2a between the SiGe alloy layer 4 and the element isolation film 3. The grooves 60 function to reduce capacitance so that the collector parasitic capacitance between the base layer (SiGe alloy layer 4) and the collector layer (active region 2a) is reduced.

Further, the side wall 6 covers boundaries 50 between the grooves 60 and the element isolation film 3. Thus, the fourth embodiment has the same advantages as the first embodiment.

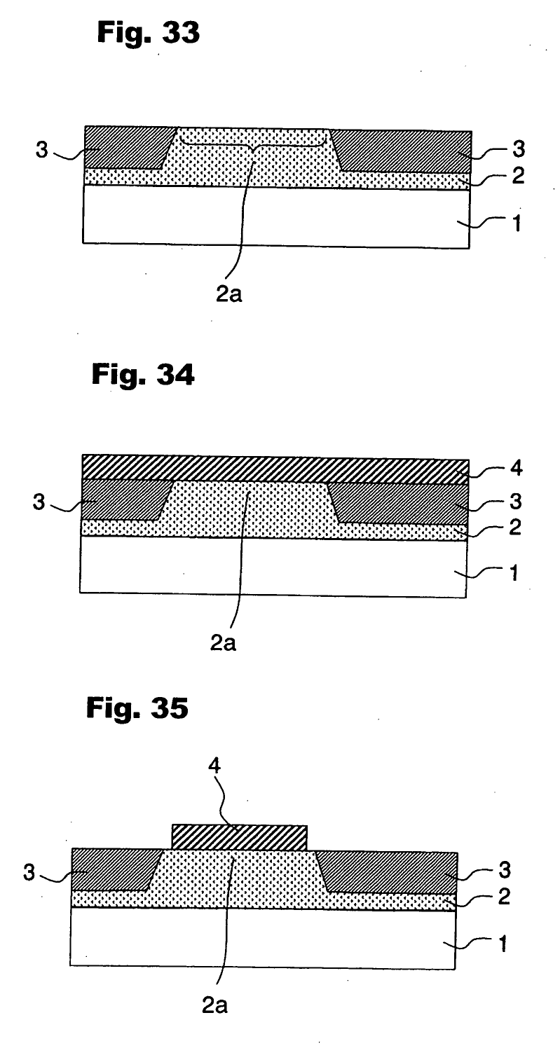

The procedures for manufacturing the semiconductor device of the fourth embodiment will now be described with reference to FIGS. 33 to 43.

[Process 1: Refer to FIG. 33]

In the same manner as in process 1 of the first embodiment, an element isolation film 3, such as an STI film, is formed on a p-type silicon substrate 1. Then, ion implantation is performed to implant n-type impurities in a portion of a collector layer 2 to form an active region 2a.

[Process 2: Refer to FIG. 34]

In the same manner as in process 2 of the first embodiment, a SiGe alloy layer 4, which is doped with boron (B) at a concentration of about 1*10¹⁹ cm⁻³, is epitaxially grown.

[Process 3: Refer to FIG. 35]

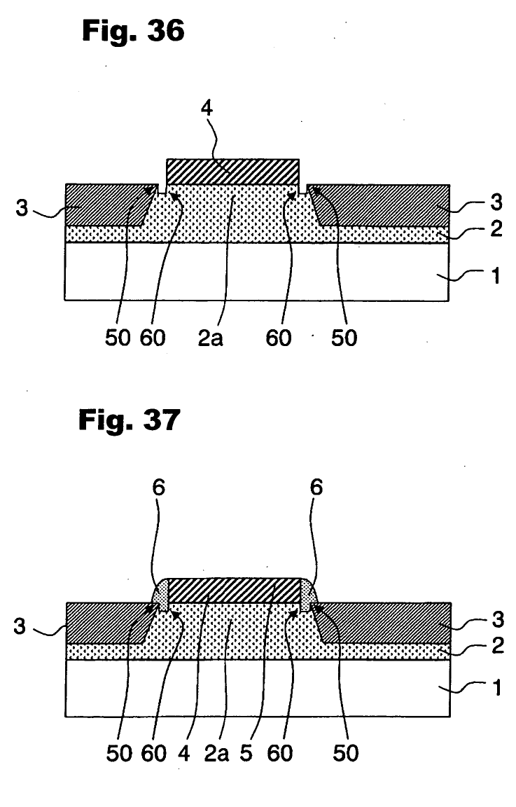

In the same manner as in process 3 of the first embodiment, a portion of the active region 2a is exposed. The exposed amount of the top surface of the active region 2a is adjusted to about 50 nm.

[Process 4: Refer to FIG. 36]

The active region 2a is subjected to dry etching using the element isolation film 3 and a resist pattern as a mask to pattern the SiGe alloy layer 4 formed in process 3. This forms grooves 60. The depth of the grooves 60 is, for example, about 100 nm. The depth of the grooves 60 is freely adjusted by changing the etching time.

In process 4, the groove 60 is self-aligned by etching so that the surface of the collector layer 2 (active region 2a) excluding a base-collector junction part is selectively removed. This enables the groove 60 with the largest opening that can be formed in the collector layer 2 (active region 2a). Even if the active region 2a and the resist pattern that is used to process the SiGe alloy layer 4 are misaligned with each other, the SiGe alloy layer 4 and the active region 2a are processed to have the same width.

[Process 5: Refer to FIG. 37]

In the same manner as in process 4 of the first embodiment, a side wall 6, which is a silicon oxide film, is formed to surround the SiGe alloy layer 4. Portions of the side wall 6 fill the grooves 60. The bottom surface of the side wall 6 covers at least the boundaries 50 between the groove 60 and the element isolation film 3 under a polycrystalline silicon film 7.

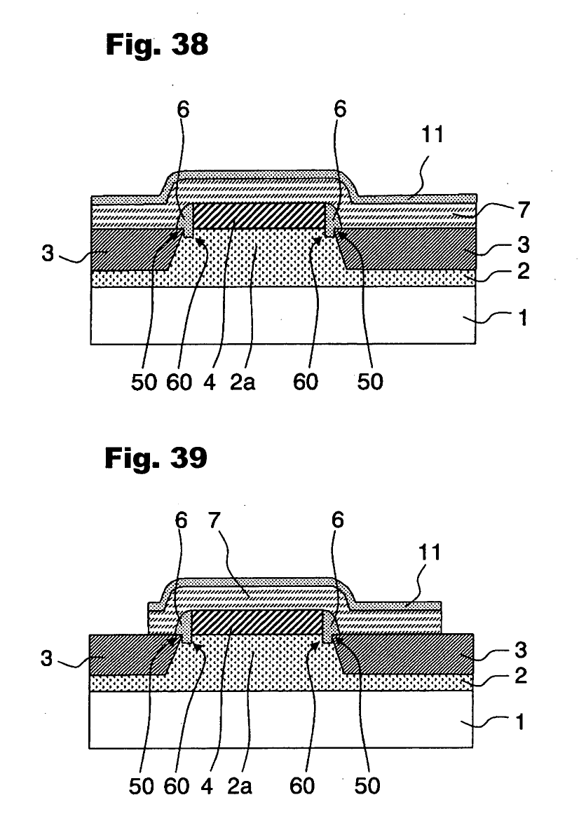

In the same manner as in the second embodiment, the side wall 6 may have projections 70 (refer to FIG. 17), which project above the top surface of the SiGe alloy layer 4.

[Process 6: Refer to FIG. 38]

In the same manner as in process 5 of the first embodiment, a polycrystalline silicon film 7 and a silicon nitride film 11 are formed. Arsenic (As) or phosphorus (P) may be used as the n-type impurities. The thickness of the polycrystalline silicon film 7 is about 200 nm. The thickness of the silicon nitride film 11 is about 100 nm.

[Process 7: Refer to FIG. 39]

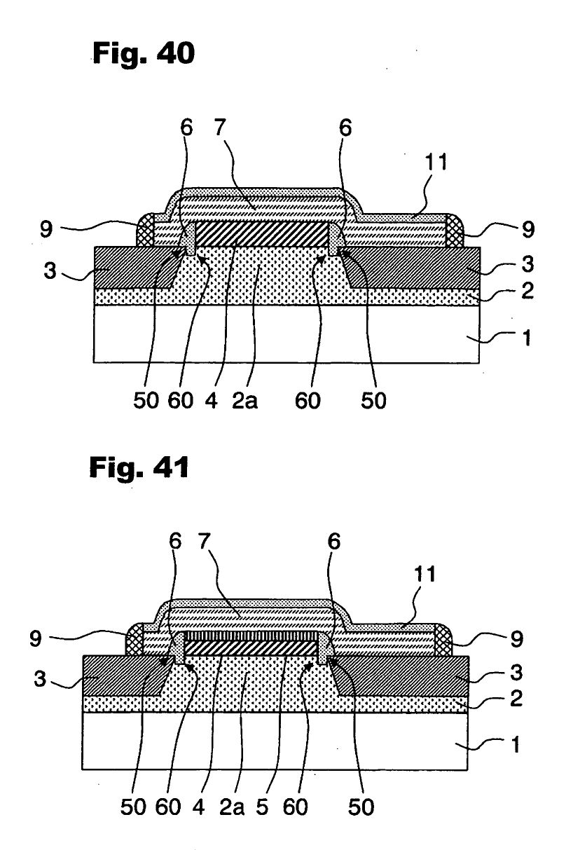

In the same manner as in process 6 of the first embodiment, etching is performed to remove unnecessary portions of the silicon nitride film 11 and the polycrystalline silicon film 7. As a result, a linear polyethylene silicon film 7 is formed as shown in FIG. 31.

[Process 8: Refer to FIG. 40]

In the same manner as in process 7 of the first embodiment, a side wall 9, which is a silicon oxide film, is formed to surround the silicon nitride film 11 and the polycrystalline silicon film 7. The thickness of the side wall 9 is about 200 nm.

[Process 9: Refer to FIG. 41]

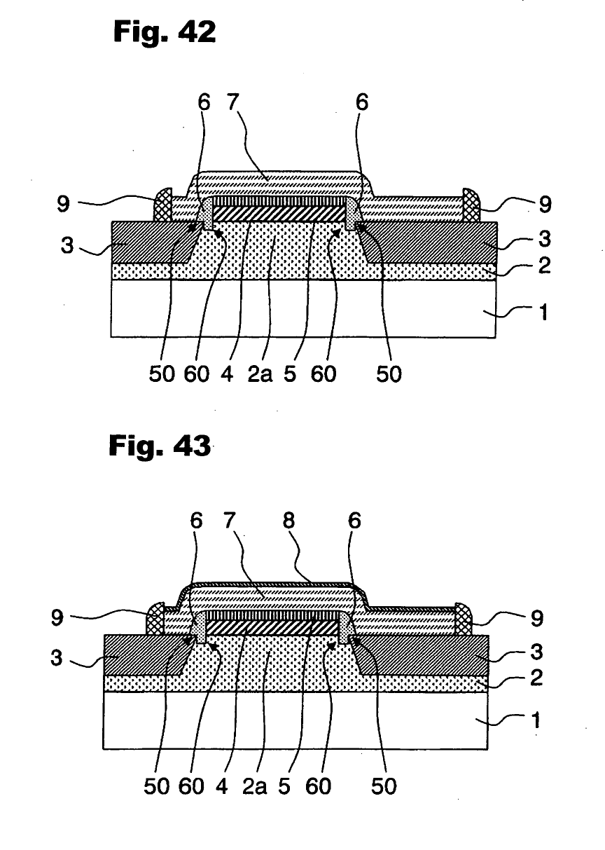

In the same manner as in process 8 of the first embodiment, heat treatment is performed to diffuse the n-type impurities in the polycrystalline silicon film 7 into the SiGe alloy layer 4 to form an n-type diffusion layer 5.

[Process 10: Refer to FIG. 42]

In the same manner as in process 9 in the first embodiment, the silicon nitride film 11 is removed.

[Process 11: Refer to FIG. 43]

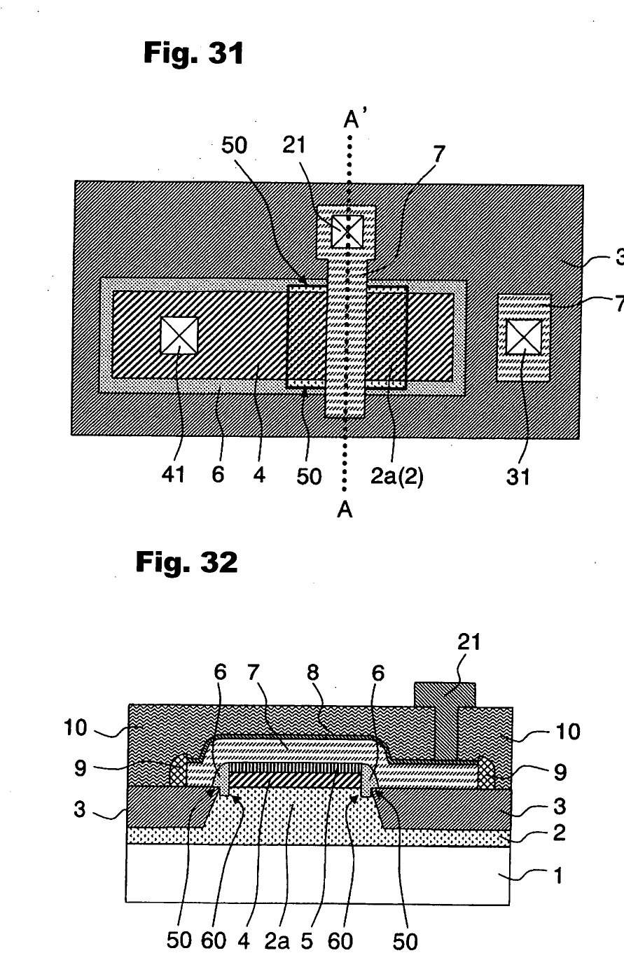

In the same manner as in process 10 of the first embodiment, a cobalt silicide film 8 is formed on the surface of the polycrystalline silicon film 7 and the surface of the p⁺ diffusion layer (not shown), which functions as an external base layer.

[Process 12: Refer to FIG. 32]

In the same manner as in process 11 of the first embodiment, an interlayer dielectric 10 is deposited on a semiconductor substrate. A collector electrode 31, a base electrode 41, and an emitter electrode 21 of an NPN transistor are formed. In this way, the bipolar transistor (semiconductor device) having an NPN transistor is manufactured.

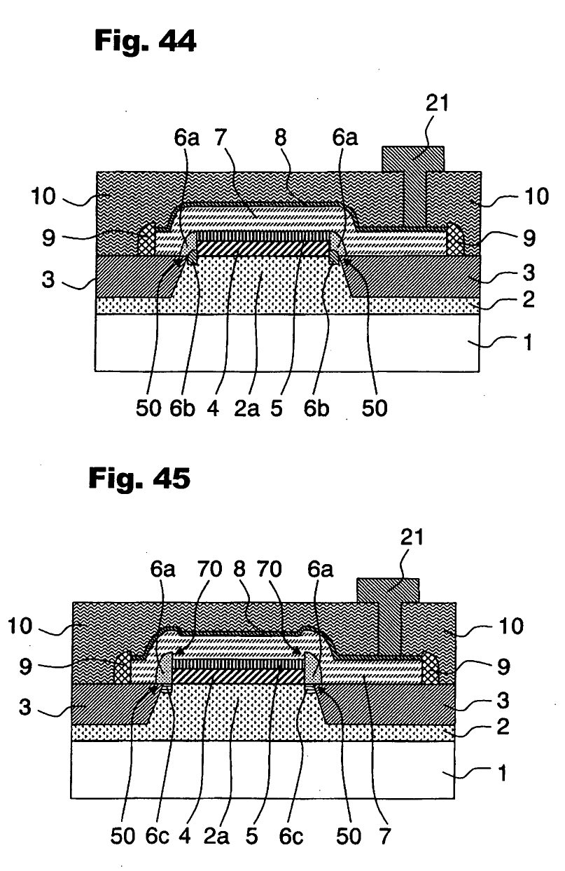

A heterojunction bipolar transistor including a SiGe alloy base layer according to a fifth embodiment of the present invention will now be described with reference to FIG. 44 focusing on its differences from the transistor of the fourth embodiment.

In the fifth embodiment, the grooves 60 are filled with a lower insulative film 6b. A side surface of a SiGe alloy layer 4 and a side surface of an n-type diffusion layer 5 are surrounded by an upper side wall 6a.

The lower insulative film 6b is one example of a first insulative film of the present invention. The upper side wall 6a is one example of a second insulative film of the present invention.

To form the lower insulative film 6b, a silicon oxide film, which is doped with phosphorus or boron, (e.g., a PSG (phospho-silicate glass) film, a BSG (boro-silicate glass) film, or a BPSG (boro-phospho-silicate glass) film), is first formed to have a thickness of about 50 nm, and then the entire film surface is etched back by dry etching. The silicon oxide film doped with phosphorus or boron exhibits a relatively high fluidity during formation of the film. This feature fills the grooves 60 with the silicon oxide film without any void (gap).

An insulative film such as a non-doped silicon oxide film or silicon nitride film may be used as the lower insulative film 6b.

To form the upper side wall 6a, a film of silicon oxide is first formed by CVD. Then, dry etching is performed to etch back the entire film surface in the same manner as in the fourth embodiment. As a result, the upper side wall 6a is formed to surround the SiGe alloy layer 4. As one example, the silicon oxide film is formed by heating a mixture of tetra ethoxy silane (TEOS) and oxygen (O₂) at a temperature of about 720° C. The thickness of the silicon oxide film is about 100 nm. The upper side wall 6a covers at least the boundaries 50 between the lower insulative film 6b and the element isolation film 3 under the polycrystalline silicon film 7.

The fifth embodiment has the same advantages as the fourth embodiment.

The upper side wall 6a and the lower insulative film 6b may be formed using the same silicon oxide films. In this case, the upper side wall 6a and the lower insulative film 6b may be formed at the same. This reduces the number of manufacturing processes and reduces manufacturing cost for the bipolar transistor (semiconductor device).

A heterojunction bipolar transistor including a SiGe alloy base layer according to a sixth embodiment of the present invention will now be described with reference to FIG. 45 focusing on its differences from the transistor of the fourth embodiment. In the sixth embodiment, an impurity region 6c is formed in the surface of an active region 2a between a SiGe alloy layer 4 and an element isolation film 3. The impurity region 6c is formed by adding reversed conductive impurities, which conduction type is reversed from that of the conduction impurities contained in the active region 2a. An upper side wall 6a is formed on the impurity region 6c.

The upper side wall 6a covers the boundaries 50 between the impurity region 6c and the element isolation film 3. Thus, the sixth embodiment has the same advantages as the first embodiment.

The impurity region 6c, which is formed by adding reversed conductive impurities to the active region 2a containing conductive impurities, is formed in the surface of the active region 2a between the SiGe alloy layer 4 and the element isolation film 3. The impurity region 6c functions to reduce capacitance as compared with when the impurity region 6c is not formed (when the corresponding part functions as a part of the active region 2a). This reduces the collector parasitic capacitance between the base layer and the collector layer (active region).

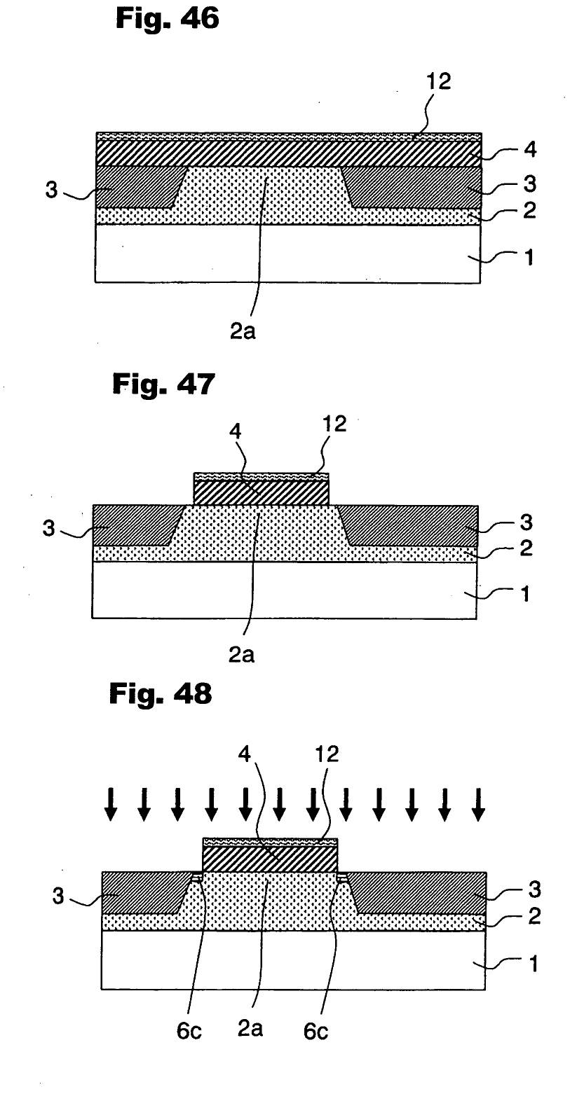

The manufacturing processes of the semiconductor device according to the sixth embodiment will now be described with reference to FIGS. 46 to 50 focusing on its differences from the fourth embodiment.

[Process 2a: Refer to FIG. 46]

After a SiGe alloy layer 4 is formed through processes 1 and 2 of the fourth embodiment (FIGS. 33 and 34), CVD is performed to form a silicon nitride film 12 on the SiGe alloy layer 4. The thickness of the silicon nitride film 12 is about 100 nm.

[Process 3a: Refer to FIG. 47]

Lithography is performed to form a resist pattern. Then, dry etching is performed to remove an unnecessary portion of the silicon nitride film 12 and then an unnecessary portion of the SiGe alloy layer 4. This exposes a portion of the active region 2a. The exposed amount of the active region 2a is about 50 nm.

[Process 4a: Refer to FIG. 48]

Ion implantation is performed to implant boron (B) into the exposed portion of the active region 2a by using the element isolation film 3 and the pattern used to form the SiGe alloy layer 4 as a mask. Then, heat treatment is performed to activate the active region 2a. As a result, an impurity region 6c is formed in the surface of the active region 2a. As one example, BF₂ is implanted with an electron acceleration energy of about 70 keV to have a concentration of about 3*10¹⁵ cm⁻².

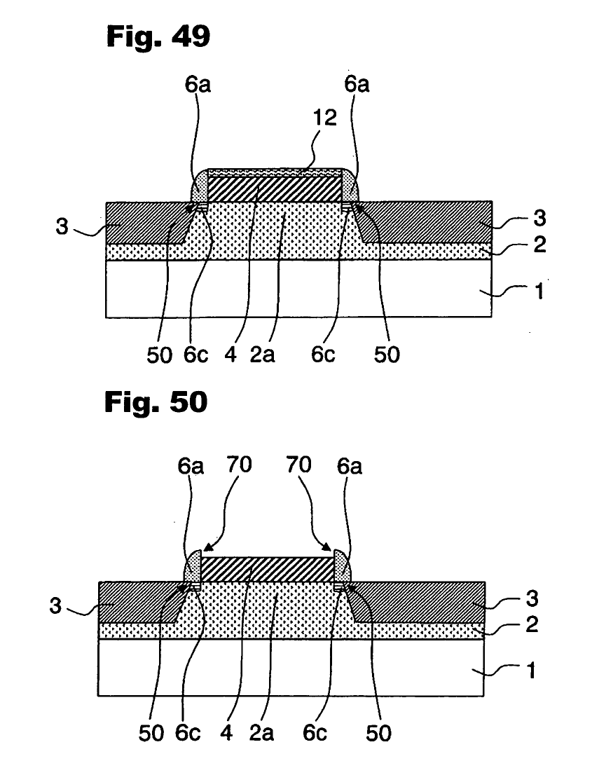

The impurity region 6c is formed by adding reversed conductive impurities (p-type impurities B in the sixth embodiment) to the active region 2a containing conductive impurities (n-type impurities P in the sixth embodiment).

[Process 5a: Refer to FIG. 49]

CVD is performed to form a film of silicon oxide. Then, the entire film surface is etched back by dry etching, so that an upper side wall 6a, which is a silicon oxide film, is formed to surround the SiGe alloy layer 4. As one example, the silicon oxide film is formed by heating a mixture of tetra ethoxy silane (TEOS) and oxygen (O₂) at a temperature of about 720° C. The thickness of the silicon oxide film is about 100 nm. The upper side wall 6a is formed to at least extend over boundaries 50 between the impurity region 6c and the element isolation film 3 under the polycrystalline silicon film 7.

[Process 5b: Refer to FIG. 50]

Wet etching is performed using phosphoric acid to remove selectively only the silicon nitride film 12. As a result, a top portion of the upper side wall 6a projects above the top surface of the SiGe alloy layer 4. The height of the projections 70 of the upper side wall 6a that extends above the top surface of the SiGe alloy layer 4 is freely adjustable by increasing or decreasing the thickness of the silicon nitride film 12.

Even if differences in the etch back cause a portion of the side wall 6 to be excessively etched back, the projections 70 of the side wall 6 functions as a margin for such excessive etching and prevents the side surface of the SiGe alloy layer 4 from being exposed.

Process 5b and subsequent processes are the same as processes 6 to 12 of the fourth embodiment.

In each of the above embodiments, a titanium silicide film formed using titanium (Ti) may be used instead of the cobalt silicide film 8 that is formed using cobalt. In this case, the same advantages are obtained as when the cobalt silicide film 8 is used.

It should be apparent to those skilled in the art that the present invention may be embodied in many other specific forms without departing from the spirit or scope of the invention. Therefore, the present examples and embodiments are to be considered as illustrative and not restrictive, and the invention is not to be limited to the details given herein, but may be modified within the scope and equivalence of the appended claims.

What is claimed is:

1. A semiconductor device comprising:
a semiconductor substrate;
an element isolation film formed on the semiconductor substrate;
an active region formed on the semiconductor substrate surrounded by the element isolation film, the active region functioning as a collector layer;
a base layer formed on the active region;
an emitter layer formed on the base layer;
a first insulative film covering a side of the emitter layer and a side of the base layer;
a conductive film contacting the emitter layer and traversing the emitter layer, the first insulative film, and the element isolation film; and
a lead electrode connected to a portion of the conductive film above the element isolation film, wherein the first insulative film is formed under the conductive film so as to extend across a boundary between the active region and the element isolation film.

2. The semiconductor device according to claim 1, wherein the base layer is a silicon-germanium alloy layer.

3. The semiconductor device according to claim 1, wherein the conductive film is formed to contact the emitter layer and extend linearly, and the conductive film has two ends located on the element isolation film.

4. The semiconductor device according to claim 1, wherein the lead electrode is connected to the conductive film at a position separated from above the emitter layer.

5. The semiconductor device according to claim 1, wherein the first insulative film covers the boundary between the active region and the element isolation film.

6. The semiconductor device according to claim 1, wherein the emitter layer has a top surface, and the first insulative film includes a projection that extends above the top surface of the emitter layer.

7. The semiconductor device according to claim 6, wherein the projection of the first insulative film includes an inner wall extending upward from the emitter layer, the semiconductor device further comprising:
a second insulative film, formed on the top surface of the emitter layer, for covering the inner wall of the first insulative film.

8. The semiconductor device according to claim 7, wherein the second insulative film covers a boundary between the top surface of the emitter layer and the projection of the first insulative film.

9. The semiconductor device according to claim 6, wherein the emitter layer is formed by diffusing impurities from the conductive film.

10. A semiconductor device comprising:
a semiconductor substrate;
an element isolation film formed on the semiconductor substrate;
an active region surrounded by the element isolation film, the active region functioning as a collector layer and having a surface;
a base layer formed on the active region;
an emitter layer formed on the base layer;
a groove formed in the surface of the active region between the base layer and the element isolation film;
a first insulative film filling the groove;
a second insulative film covering a side of the emitter layer and a side of the base layer;
a conductive film contacting the emitter layer and traversing the emitter layer, the second insulative film, and the element isolation film; and
a lead electrode contacting the conductive film above the element isolation film, wherein the second insulative film extends across a boundary between the first insulative film and the element isolation film under the conductive film.

11. The semiconductor device according to claim 10, wherein the groove is self-aligned by performing etching using the base layer and the element isolation film as a mask.

12. The semiconductor device according to claim 10, wherein the first insulative film and the second insulative film are integrally formed from the same material.

13. The semiconductor device according to claim 10, wherein the groove extends along the periphery of the base layer.

14. The semiconductor device according to claim 10, wherein the conductive film contacts the emitter layer and extends linearly, and the conductive film has two ends located on the element isolation film.

15. A semiconductor device comprising:
a semiconductor substrate;
an element isolation film formed on the semiconductor substrate;
an active region surrounded by the element isolation film, the active region functioning as a collector layer and having a surface;
a base layer formed on the active region;
an emitter layer formed on the base layer;
an impurity region formed in the surface of the active region between the base layer and the element isolation film;
an insulative film covers a side of the emitter layer and a side of the base layer;
a conductive film contacting the emitter layer and traversing the emitter layer, the insulative film, and the element isolation film; and
a lead electrode contacting the conductive film above the element isolation film, wherein the active region contains conductive impurities, the impurity region is a region formed by adding reversed conductive impurities to the active region, and the insulative film is formed under the conductive film so as to extend across a boundary between the impurity region and the element isolation film.

16. The semiconductor device according to claim 15, wherein the conductive film contacts the emitter layer and extends linearly, and the conductive film has two ends located on the element isolation film.
